(19) United States
(12) Patent Application Publication
(10) Pub. No.: US 2025/0273585 A1
(43) Pub. Date: Aug. 28, 2025

(54) PACKAGE COMPRISING SUBSTRATES AND INTEGRATED DEVICES

(71) Applicant: QUALCOMM Incorporated, San Diego, CA (US)

(72) Inventors: Manuel ALDRETE, Encinitas, CA (US); Zhijie WANG, San Diego, CA (US); Sang-Jae LEE, San Diego, CA (US); Seongho KIM, San Diego, CA (US)

(21) Appl. No.: 18/589,819

(22) Filed: Feb. 28, 2024

(51) Int. Cl. H01L 23/538; H01L 23/00; H01L 23/31; H01L 23/48; H01L 23/498; H01L 25/00; H01L 25/065; H01L 25/10

(52) U.S. Cl. CPC H01L 23/5389; H01L 23/3128; H01L 23/481; H01L 23/49811; H01L 23/5385; H01L 24/16; H01L 24/32; H01L 24/73; H01L 25/0657; H01L 25/105; H01L 25/50; H01L 2224/16145; H01L 2224/16227; H01L 2224/32145; H01L 2224/73204

(57) ABSTRACT

A package comprising a first substrate; a first integrated device coupled to the first substrate; a second substrate; a second integrated device coupled to the second substrate; and an encapsulation layer coupled to the first substrate and the second substrate, wherein the encapsulation layer, the first integrated device and the second integrated device are located between the first substrate and the second substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a first substrate; a first integrated device coupled to the first substrate; a second substrate; a second integrated device coupled to the second substrate; and an encapsulation layer coupled to the first substrate and the second substrate, wherein the encapsulation layer, the first integrated device and the second integrated device are located between the first substrate and the second substrate.

Another example provides a method for fabricating a package. The method provides a first substrate. The method couples a first integrated device to the first substrate. The method provides a second substrate. The method couples a second integrated device to the second substrate. The method forms an encapsulation layer that is coupled to the first substrate and the second substrate, wherein the encapsulation layer, the first integrated device and the second integrated device are located between the first substrate and the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes substrates and integrated devices.

FIG. 2 illustrates an exemplary cross sectional profile view of a package that includes substrates and integrated devices.

FIG. 3 illustrates an exemplary cross sectional profile view of a package that includes substrates and integrated devices.

FIG. 4 illustrates an exemplary cross sectional profile view of a package that includes substrates and integrated devices.

FIG. 5 illustrates an exemplary cross sectional profile view of an integrated device.

FIGS. 6A-6D illustrate an exemplary sequence for fabricating a package that includes substrates and integrated devices.

FIG. 7 illustrates an exemplary flow chart of a method for fabricating a package that includes substrates and integrated devices.

FIGS. 8A-8B illustrate an exemplary sequence for fabricating a substrate.

FIG. 9 illustrates an exemplary flow chart of a method for fabricating a substrate.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a package comprising a first substrate; a first integrated device coupled to the first substrate; a second substrate; a second integrated device coupled to the second substrate; and an encapsulation layer coupled to the first substrate and the second substrate, wherein the encapsulation layer, the first integrated device and the second integrated device are located between the first substrate and the second substrate. As will be further described below, the package provides improved, efficient and/or effective electrical connections in a compact form factor.

### Exemplary Package Comprising Substrates and Integrated Devices

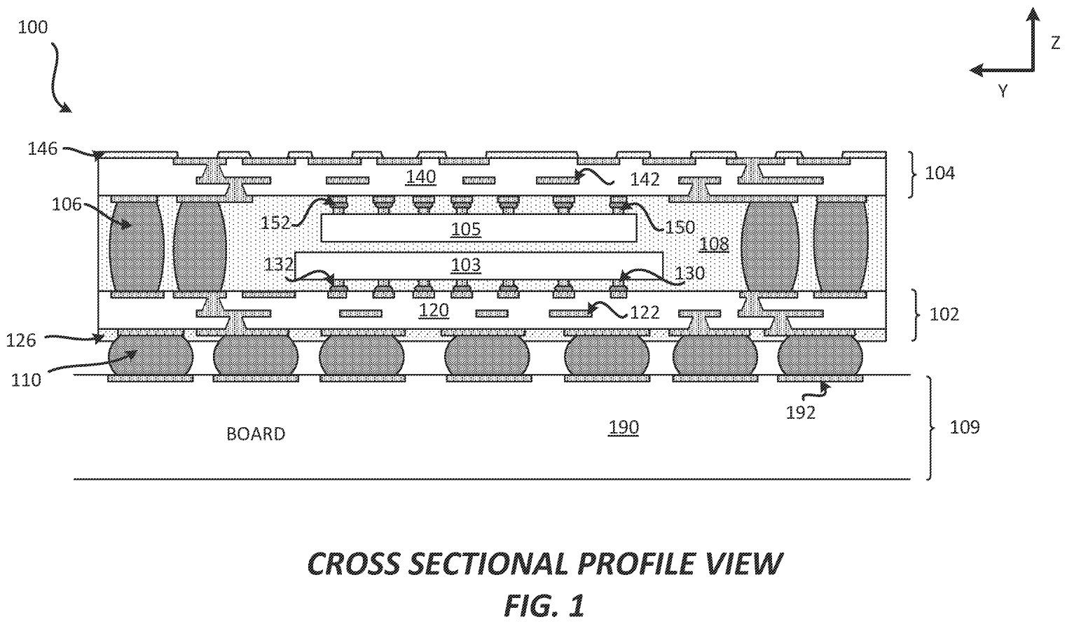

FIG. 1 illustrates a cross sectional profile view of a package 100 that includes substrates and integrated devices. The package 100 may be implemented as part of a package on package (PoP). The package 100 is coupled to a board 109 through a plurality of solder interconnects 110. The board 109 includes at least one board dielectric layer 190 and a plurality of board interconnects 192. The board 109 may include a printed circuit board (PCB).

The package 100 includes a substrate 102, a substrate 104, an integrated device 103, an integrated device 105 and an encapsulation layer 108. The substrate 102 may be a first substrate (e.g., bottom substrate). The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., bottom surface) and a second surface (e.g., top surface).

The substrate 104 may be a second substrate (e.g., top substrate). The substrate 104 includes at least one dielectric layer 140, a plurality of interconnects 142, and a solder resist layer 146. The at least one dielectric layer 140 may include at least one second dielectric layer. The plurality of interconnects 142 may include a second plurality of interconnects. The substrate 104 may include a first surface (e.g., bottom surface) and a second surface (e.g., top surface).

The integrated device 103 may be a first integrated device. The integrated device 103 may be coupled to the substrate 102 through a plurality of pillar interconnects 130 and a plurality of solder interconnects 132. The integrated device 103 may be coupled to the second surface (e.g., top surface) of the substrate 102 through a plurality of pillar interconnects 130 and a plurality of solder interconnects 132. The integrated device 103 may be coupled to the interconnects from the plurality of interconnects 122 through the plurality of pillar interconnects 130 and the plurality of solder interconnects 132. The plurality of solder interconnects 132 are touching interconnects from the plurality of interconnects 122. The integrated device 103 may include a front side and a back side.

The integrated device 105 may be a second integrated device. The integrated device 105 may be coupled to the substrate 104 through a plurality of pillar interconnects 150 and a plurality of solder interconnects 152. The integrated device 105 may be coupled to the first surface (e.g., bottom surface) of the substrate 102 through a plurality of pillar interconnects 150 and a plurality of solder interconnects 152. The integrated device 105 may be coupled to the interconnects from the plurality of interconnects 142 through the plurality of pillar interconnects 150 and the plurality of solder interconnects 152. The plurality of solder interconnects 152 are touching interconnects from the plurality of interconnects 142. The integrated device 105 may include a front side and a back side. The back side of the integrated device 105 may be closest to the back side of the integrated device 103. The surface of the back side of the integrated device 105 may be directed in the direction of the surface of the back side of the integrated device 103. The surface of the back side of the integrated device 103 may be directed in the direction of the surface of the back side of the integrated device 105.

The substrate 104 is coupled to the substrate 102 through a plurality of solder interconnects 106. The plurality of solder interconnects 106 are located between the substrate 102 and the substrate 104. The plurality of solder interconnects 106 are coupled to the plurality of interconnects 122 and the plurality of interconnects 142. The integrated device 103 and the integrated device 105 may be located between the substrate 102 and the substrate 104.

The encapsulation layer 108 is coupled to the substrate 102 and the substrate 104. The encapsulation layer 108 is located between the substrate 102 and the substrate 104. The encapsulation layer 108 may at least partially encapsulate the integrated device 103, the integrated device 105 and/or the plurality of solder interconnects 106. The encapsulation layer 108 may touch the substrate 102, the substrate 104, the integrated device 103, the integrated device 105 and/or the plurality of solder interconnects 106. For example, the encapsulation layer 108 may touch the back side of the integrated device 105 and/or the side surface of the integrated device 105. The encapsulation layer 108 may touch the back side of the integrated device 103 and/or the side surface of the integrated device 103. The encapsulation layer 108 may be located laterally of the integrated device 103, the integrated device 105 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

An electrical path between the integrated device 103 and the integrated device 105 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 106, (iv) at least one interconnect from the plurality of interconnects 142, (v) a solder interconnect from the plurality of solder interconnects 152, and/or (vi) a pillar interconnect from the plurality of pillar interconnects 150.

An electrical path between the integrated device 103 and the board 109 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 110, and/or (v) at least one board interconnect from the plurality of board interconnects 192.

An electrical path between the integrated device 105 and the board 109 may include (i) a pillar interconnect from the plurality of pillar interconnects 150, (ii) a solder interconnect from the plurality of solder interconnects 152, (iii) at least one interconnect from the plurality of interconnects 142, (iv) a solder interconnect from the plurality of solder interconnects 106, (v) at least one interconnect from the plurality of interconnects 122, (vi) a solder interconnect from the plurality of solder interconnects 110, and/or (vii) a board interconnect from the plurality of board interconnects 192.

Providing two integrated devices between two substrates help provide a more compact package, while providing a low cost package that is still effective and efficient at providing high speed electrical connections.

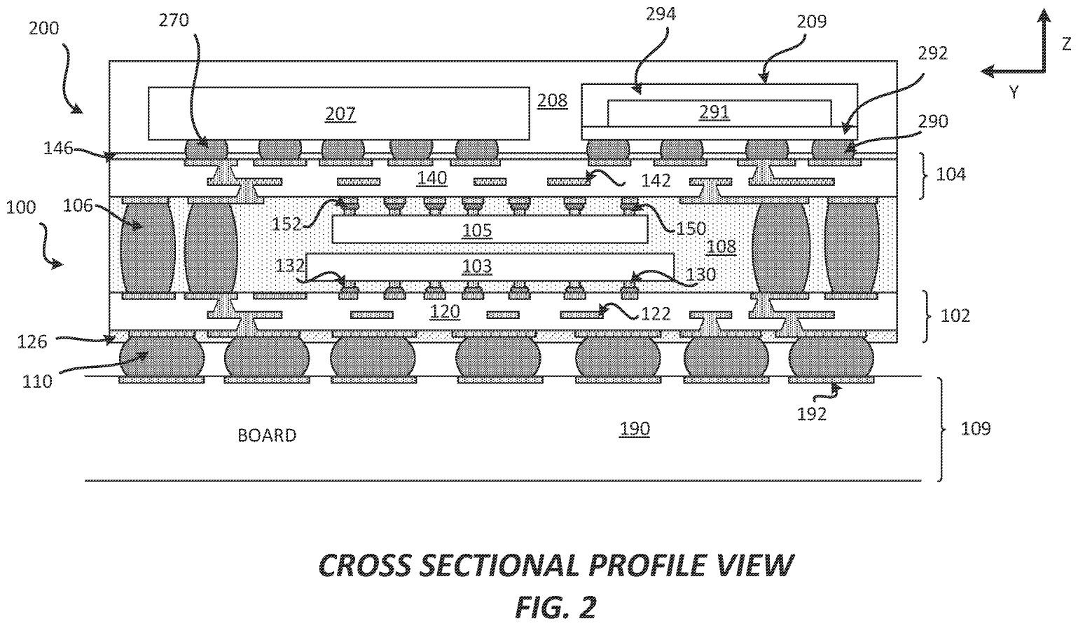

FIG. 2 illustrates a package 200. The package 200 may include the package 100, an integrated device 207, a package 209, and an encapsulation layer 208. The package 200 may include a package on package (PoP). The integrated device 207 and the package 209 are coupled to the package 100.

The integrated device 207 is coupled to the substrate 104 through a plurality of solder interconnects 270. The package 209 is coupled to the substrate 104 through a plurality of solder interconnects 290. The encapsulation layer 208 is coupled to a surface (e.g., top surface) of the substrate 104. The encapsulation layer 208 may at least partially encapsulate the integrated device 207 and the package 209. The package 209 may include a substrate 292, an integrated device 291 and an encapsulation layer 294. The substrate 292 may be a laminated substrate. The substrate 292 may include at least one dielectric layer and a plurality of interconnects. The integrated device 291 is coupled to the substrate 292. The integrated device 291 may be coupled to the substrate 292 through at least a plurality of solder interconnects. The encapsulation layer 294 may be coupled to the substrate 292. The encapsulation layer 294 may at least partially encapsulate the integrated device 291.

An electrical path between the integrated device 207 and the board 109 may include (i) a solder interconnect from the plurality of solder interconnects 270, (ii) at least one interconnect from the plurality of interconnects 142, (iii) a solder interconnect from the plurality of solder interconnects 106, (iv) at least one interconnect from the plurality of interconnects 122, (v) a solder interconnect from the plurality of solder interconnects 110, and/or (vi) a board interconnect from the plurality of board interconnects 192.

An electrical path between the integrated device 103 and the integrated device 207 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 106, (iv) at least one interconnect from the plurality of interconnects 142, and/or (v) a solder interconnect from the plurality of solder interconnects 270.

An electrical path between the integrated device 207 and the integrated device 105 may include (i) a solder interconnect from the plurality of solder interconnects 270, (ii) at least one interconnect from the plurality of interconnects 142, (iii) a solder interconnect from the plurality of solder interconnects 152, and/or (iv) a pillar interconnect from the plurality of pillar interconnects 150.

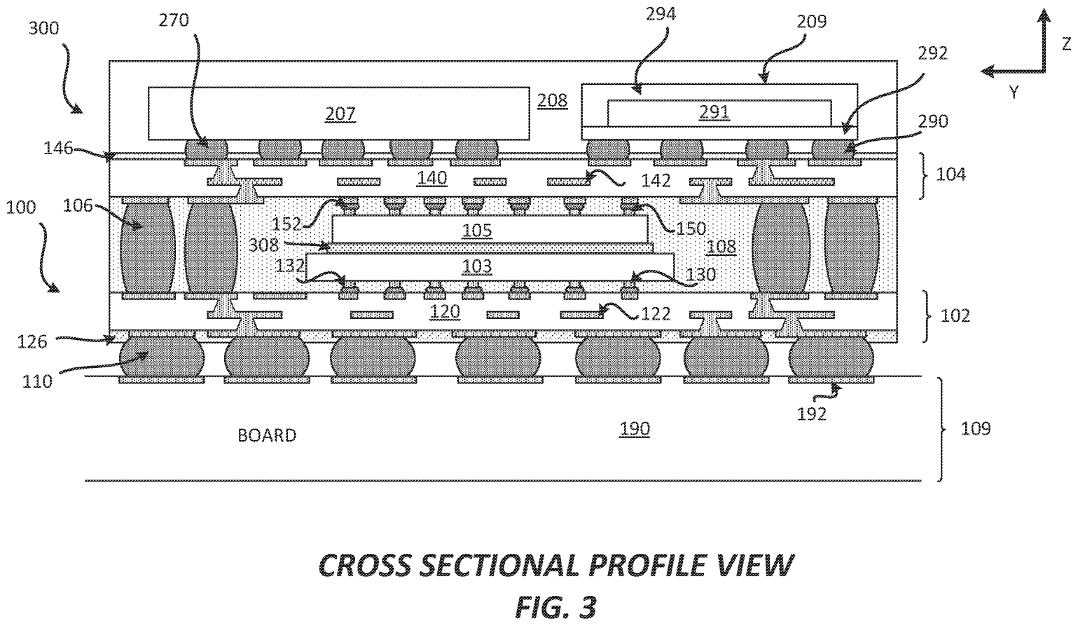

FIG. 3 illustrates a package 300. The package 300 is similar to the package 200 of FIG. 2, and may include similar components as the package 200. The package 300 may include the package 100, an integrated device 207, a package 209, and an encapsulation layer 208. The package 200 may include a package on package (PoP). The integrated device 207 and the package 209 are coupled to the package 100. The package 100 may include and adhesive 308. The adhesive 308 may include a die attach film (DAF). The adhesive 308 may be coupled to and touch the integrated device 103 and the integrated device 105. For example, the adhesive 308 may be coupled to and touch the back side of the integrated device 103 and the back side of the integrated device 105. The adhesive 308 may be located between the integrated device 103 and the integrated device 105. The adhesive 308 may include a paste located between the integrated device 103 and the integrated device 105. The adhesive 308 may help reduce the gap and/or the space between the integrated device 103 and the integrated device 105. Reducing the gap and/or the space between the integrated device 103 and the integrated device 105 may help reduce the overall height of the package 100 and/or the package 300, thus providing a more compact form factor for the package 100 and/or the package 300.

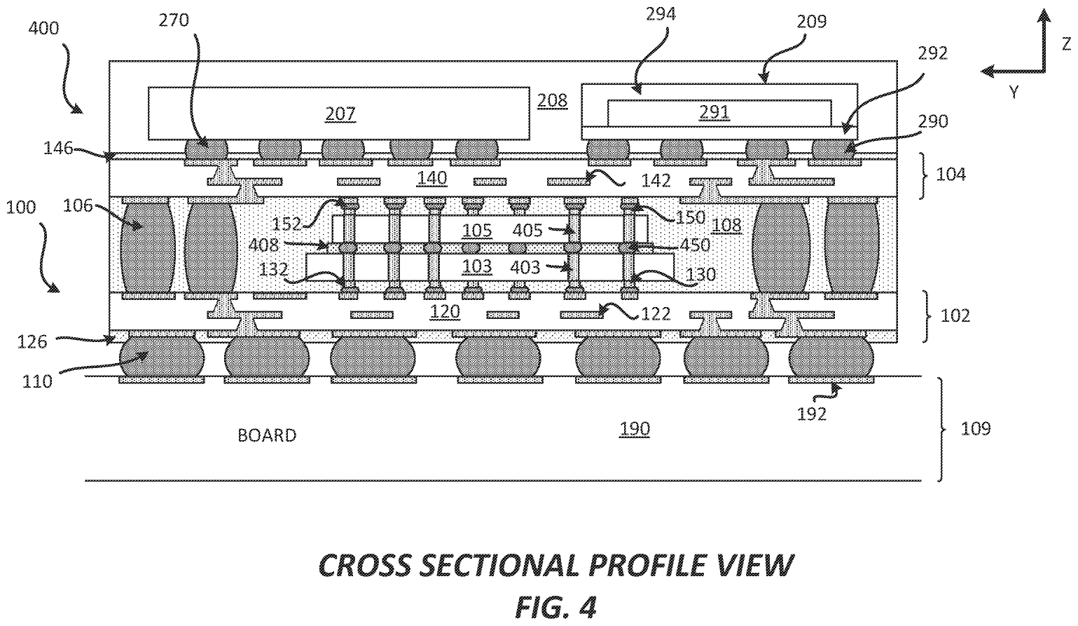

FIG. 4 illustrates a package 300. The package 400 is similar to the package 200 of FIG. 2 and/or the package 300 of FIG. 3, and may include similar components as the package 200 and/or the package 300. The package 400 may include the package 100, an integrated device 207, a package 209, and an encapsulation layer 208. The package 400 may include a package on package (PoP). The integrated device 207 and the package 209 are coupled to the package 100. The package 100 may include an underfill 408 and a plurality of solder interconnects 450. The underfill 408 may include a different material from the encapsulation layer 208.

The integrated device 103 is coupled to the integrated device 105 through the plurality of solder interconnects 450. The plurality of solder interconnects 450 and the underfill 408 may be located between the integrated device 103 and the integrated device 105. The plurality of solder interconnects 450 are coupled to the back side of the integrated device 103 and the back side of the integrated device 105. In one example, the plurality of solder interconnects 450 are coupled to the back side metallization portion of the integrated device 103 and the back side metallization portion of the integrated device 105. The plurality of solder interconnects 450 may be coupled to (i) the back side metallization interconnects and/or through substrate vias of the integrated device 103 and (ii) the back side metallization interconnects and/or through substrate vias of the integrated device 105. The integrated device 103 may be configured to be electrically coupled to the integrated device 105 through the plurality of solder interconnects 450. The integrated device 103 may include a plurality of through substrate vias 403. The integrated device 105 may include a plurality of through substrate vias 405.

An electrical path between the integrated device 103 and the integrated device 105 may include a through substrate via from the plurality of through substrate vias 403, a solder interconnect from the plurality of solder interconnects 450 and a through substrate via from the plurality of through substrate vias 405. The shorted electrical path between the integrated device 103 and the integrated device 105 helps provide improved performance for the package 100 and/or the package 400.

### Exemplary Integrated Device

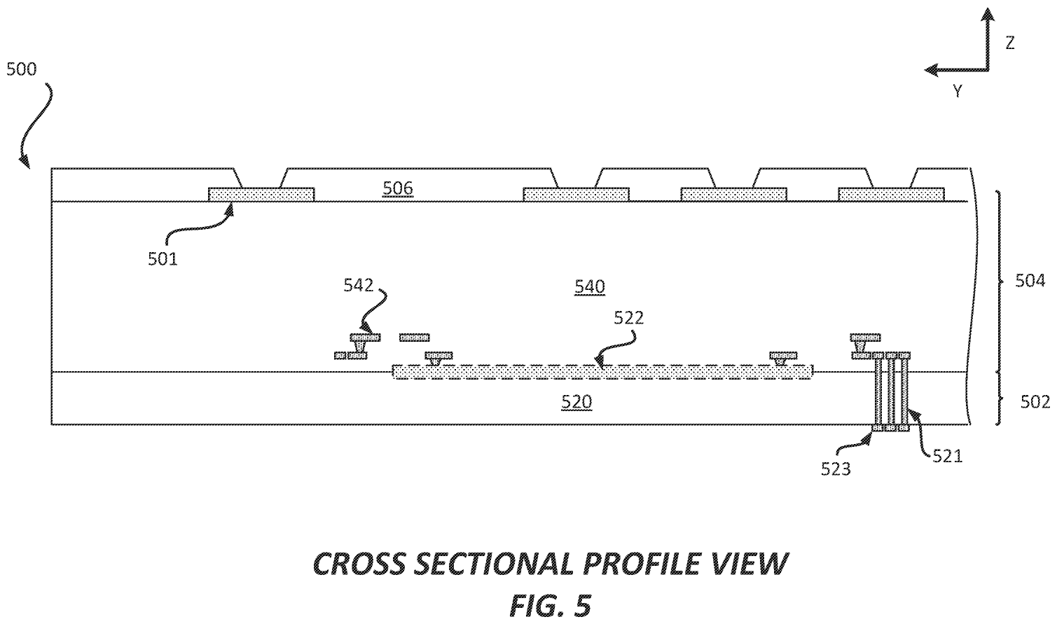

FIG. 5 illustrates a cross sectional profile view of an integrated device 500 that includes a die substrate. The integrated device 500 may represent the integrated device 103 and/or the integrated device 105. The integrated device 500 includes a die substrate portion 502 and a die interconnection portion 504. The die substrate portion 502 includes a die substrate 520, an active region 522 and a plurality of through substrate vias 521. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520.

The die substrate 520 may include silicon (Si). The die substrate 520 may comprise a bulk silicon. The bulk silicon may include a monolith silicon. The plurality of through substrate vias 521 may extend through the die substrate 520. Different implementations may have different thicknesses for the die substrate 520.

The die interconnection portion 504 includes at least one dielectric layer 540 and a plurality of die interconnects 542. The die interconnection portion 504 is coupled to the die substrate portion 502. The plurality of die interconnects 542 is coupled to the active region 522 of the die substrate portion 502. The plurality of die interconnects 542 may be coupled to the plurality of through substrate vias 521. The die interconnection portion 504 may also include a plurality of pad interconnects 501 and a passivation layer 506. In some implementations, a back end of line (BEOL) process may be used to fabricate the die interconnection portion 504. A plurality of metallization interconnects 523 may be coupled to the plurality of through substrate vias 521. The plurality of metallization interconnects 523 may be part of a back side metallization portion of the integrated device 500. In some implementations, a front side of the integrated device 500 may be a side that includes the plurality of pad interconnects 501. In some implementations, a back side of the integrated device 500 may be a side that includes the die substrate 520, the plurality of through substrate vias 521 and/or the plurality of metallization interconnects 523.

In some implementations, an electrical path to and/or from an active region 522 may include at least one die interconnect from the plurality of die interconnects 542, at least one through substrate via from the plurality of through substrate vias 521. In some implementations, an electrical path to and/or from an active region 522 may include at least one die interconnect from the plurality of die interconnects 542, at least one pad interconnect from the plurality of pad interconnects 501.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300, 400) may be implemented in a radio frequency (RF) package. The RF package may be a radio frequency front end (RFFE) package. A package (e.g., 100, 200, 300, 400) may be configured to provide Wireless Fidelity (WiFi) communication and/or cellular communication (e.g., 2G, 3G, 4G, 5G). The packages (e.g., 100, 200, 300, 400) may be configured to support Global System for Mobile (GSM) Communications, Universal Mobile Telecommunications System (UMTS), and/or Long-Term Evolution (LTE). The packages (e.g., 100, 300, 400) may be configured to transmit and receive signals having different frequencies and/or communication protocols.

Having described various packages, a sequence for fabricating a package will now be described below.

### Exemplary Sequence for Fabricating a Package Comprising Substrates and Integrated Devices

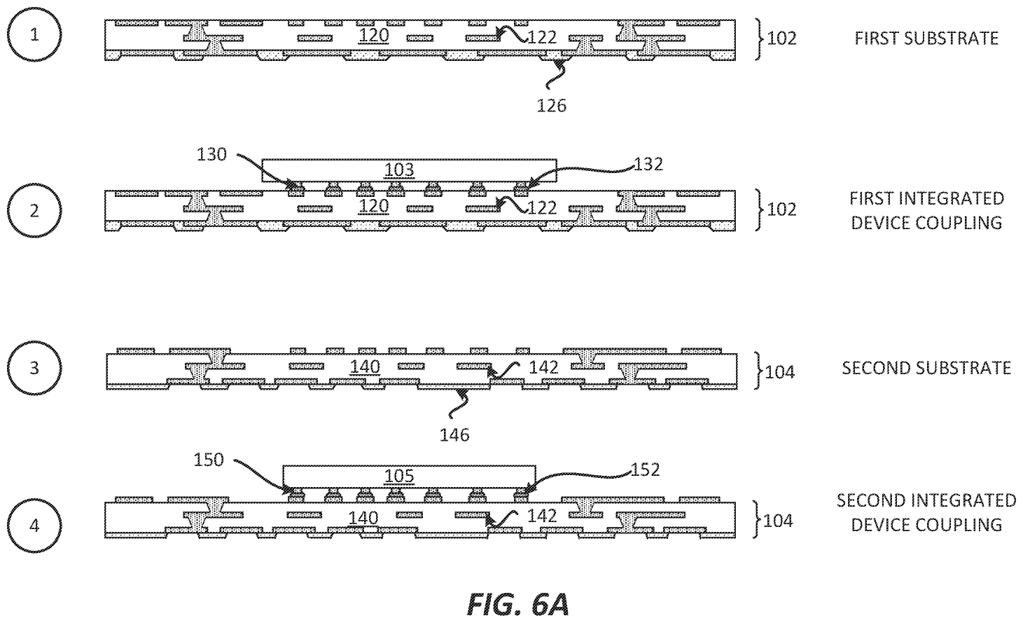

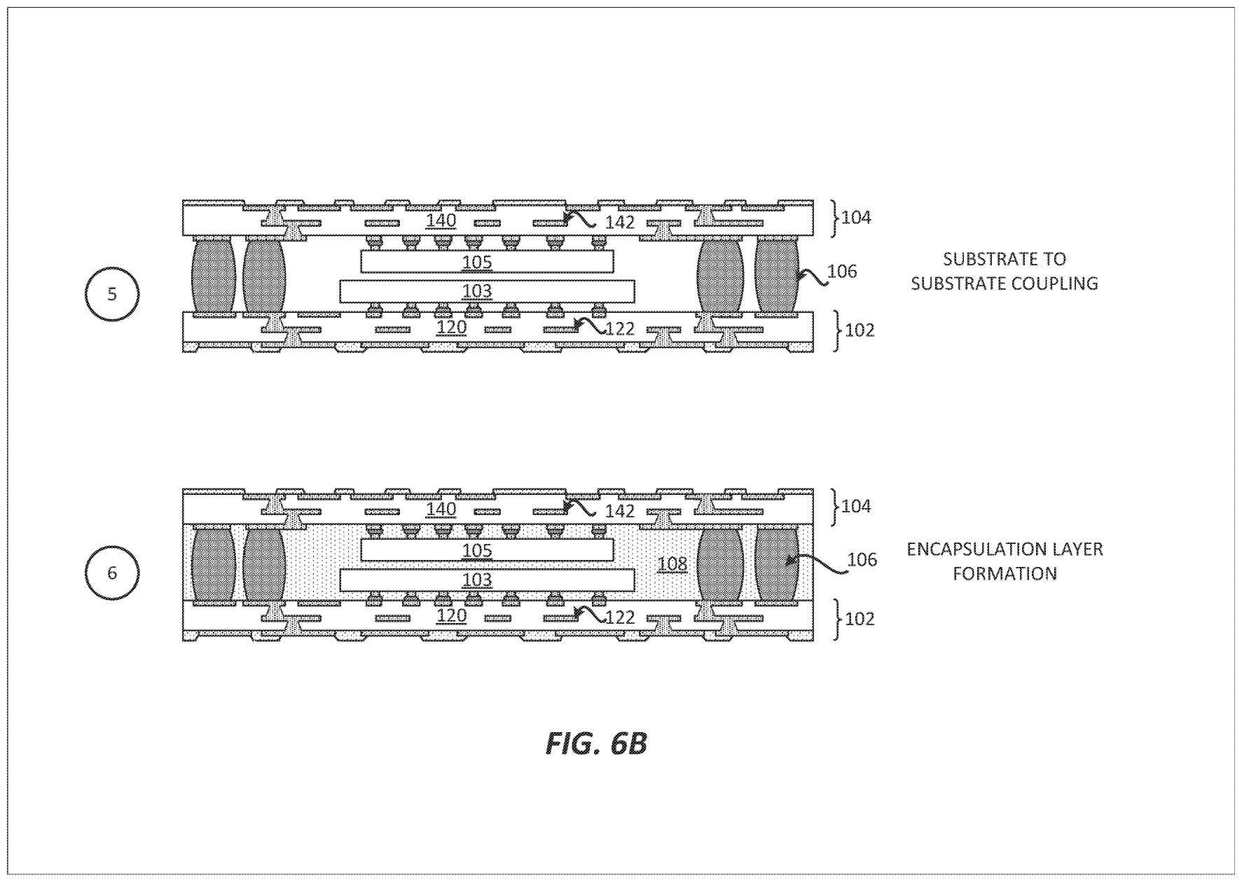

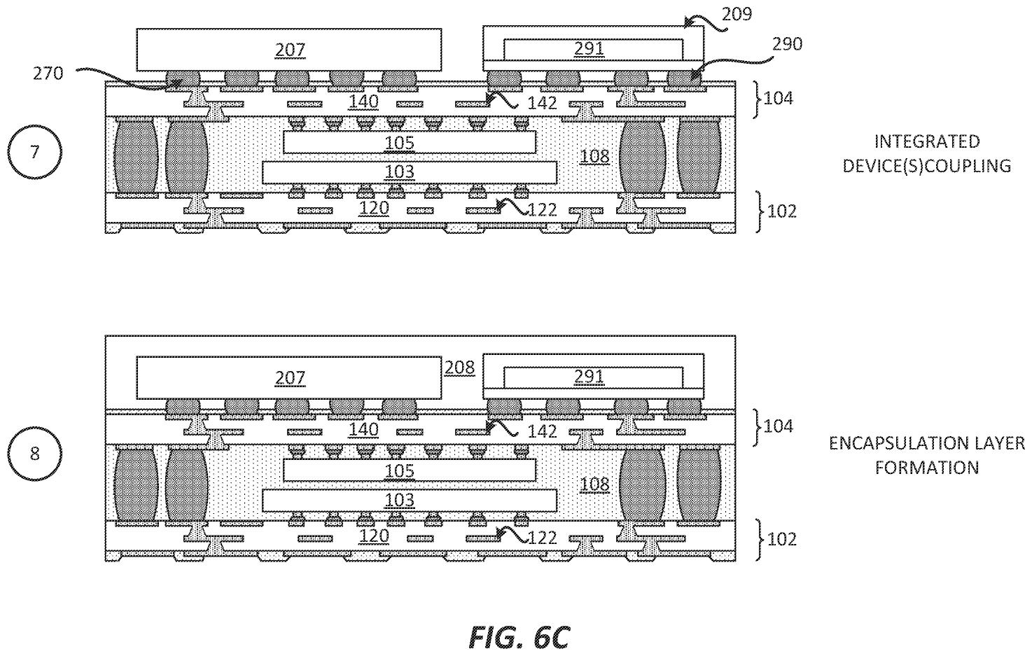

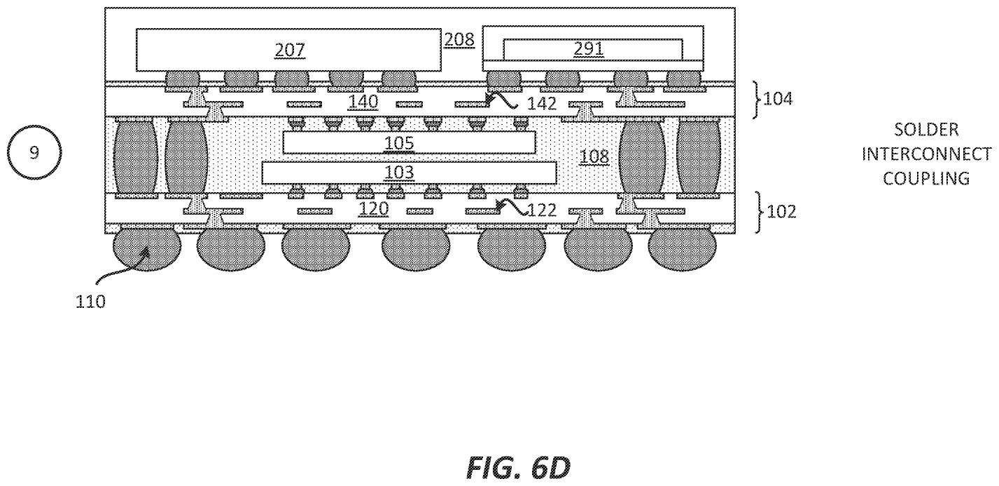

In some implementations, fabricating a package includes several processes. FIGS. 6A-6D illustrate an exemplary sequence for providing or fabricating a package. In some implementations, the sequence of FIGS. 6A-6D may be used to provide or fabricate the package 200. However, the process of FIGS. 6A-6D may be used to fabricate any of the packages (e.g., 300, 400) described in the disclosure.

It should be noted that the sequence of FIGS. 6A-6D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

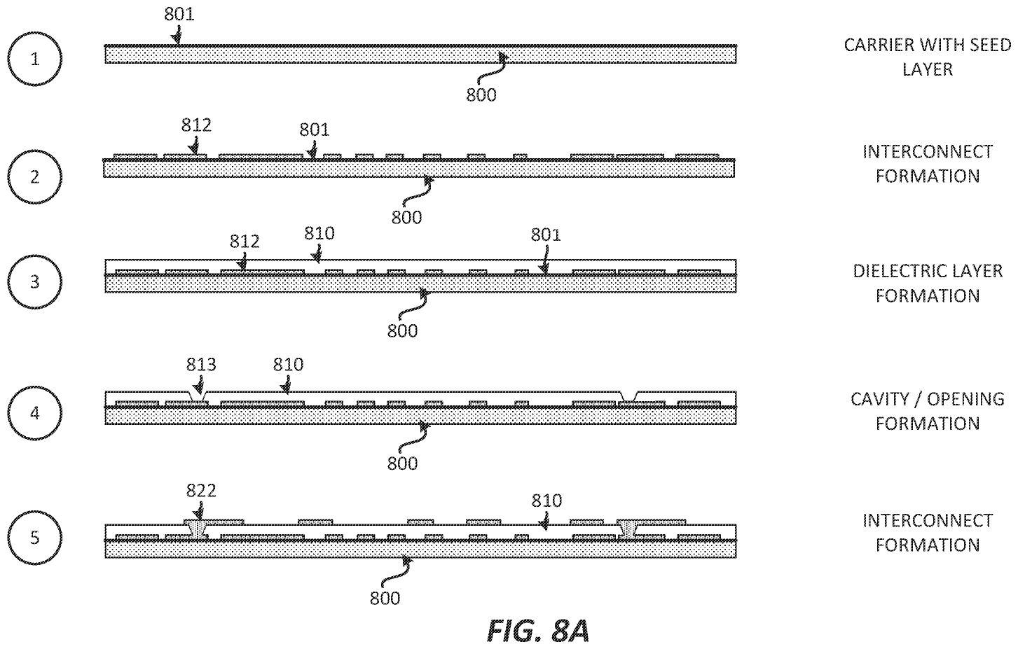

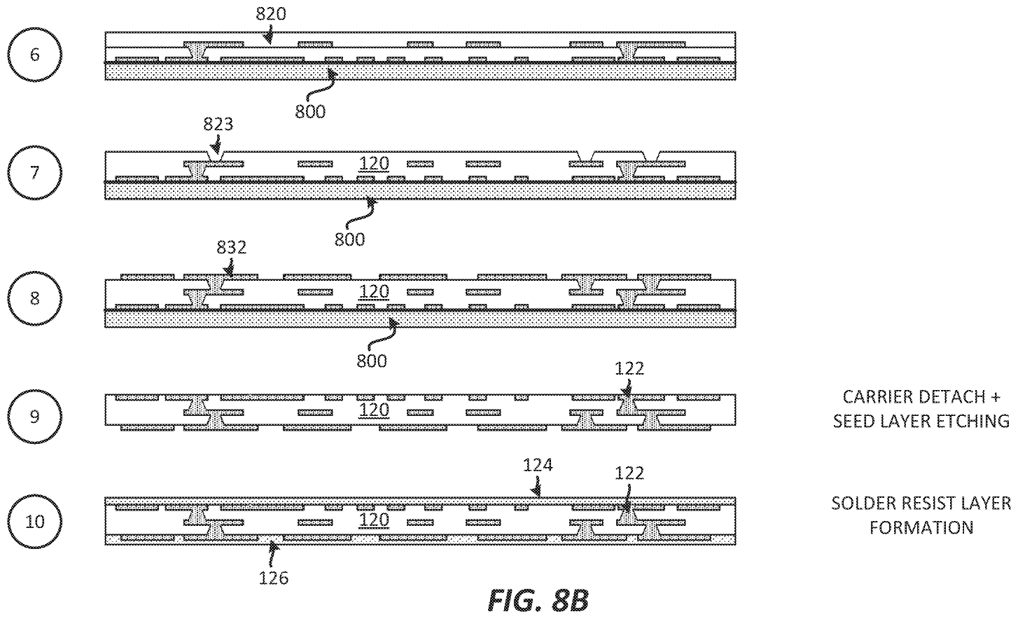

Stage 1, as shown in FIG. 6A, illustrates a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described in FIGS. 8A-8B.

Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 3 illustrates a state after a substrate 104 is provided. The substrate 104 may be a second substrate. The substrate 104 includes at least one dielectric layer 140, a plurality of interconnects 142 and a solder resist layer 146. The substrate 104 may include a first surface (e.g., top surface) and a second surface (e.g., bottom surface). The substrate 104 may be fabricated using the method as described in FIGS. 8A-8B.

Stage 4 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 5, as shown in FIG. 6B, illustrates a state after the substrate 104 is coupled to the substrate 102 through the plurality of solder interconnects 106. A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of interconnects 122 and the plurality of interconnects 142. The substrate 104 is coupled to the substrate 102 such that the integrated device 103 and the integrated device 105 are located between the substrate 102 and the substrate 104. In some implementations, a plurality of solder interconnects are provided and/or coupled to the substrate 102 and the substrate 104 separately before coupling the substrate 104 to the substrate 102. In some implementations, the integrated device 105 may be coupled to the integrated device 103 through and adhesive (as shown in FIG. 3) or through a plurality of solder interconnects (as shown in FIG. 4). An underfill may be provided between the integrated device 105 may be coupled to the integrated device 103.

Stage 6 illustrates a state after an encapsulation layer 108 is provided between the substrate 102 and the substrate 104. The encapsulation layer 108 may at least partially encapsulate the integrated device 103, the integrated device 105, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 7, as shown in FIG. 6C, illustrates a state after an integrated device 207 is coupled to the first surface (e.g., top surface) of the substrate 104. The integrated device 207 may be a third integrated device. The integrated device 207 may be coupled to the substrate 104 through the plurality of solder interconnects 270. A solder reflow process may be used to couple the integrated device 207 to the substrate 104.

Stage 7 also illustrates a state after the package 209 is coupled to the first surface (e.g., top surface) of the substrate 104. The package 209 may be coupled to the substrate 104 through the plurality of solder interconnects 290. A solder reflow process may be used to couple the package 209 to the substrate 104.

Stage 8 illustrates a state after an encapsulation layer 208 is provided and coupled to the substrate 104. The encapsulation layer 208 may at least partially encapsulate the integrated device 207 and the package 209. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

Stage 9, as shown in FIG. 6D, illustrates a state after a plurality of solder interconnects 110 are coupled to the second surface of the substrate 102. A solder reflow process may be used to couple the plurality of solder interconnects 110 to the substrate 102. Stage 9 may illustrate the package 200. The package 200 may be fabricated one at a time or may be fabricated together as part of one or more wafers and then singulated into individual packages.

### Exemplary Flow Diagram of a Method for Fabricating a Package Comprising Substrates and Integrated Devices

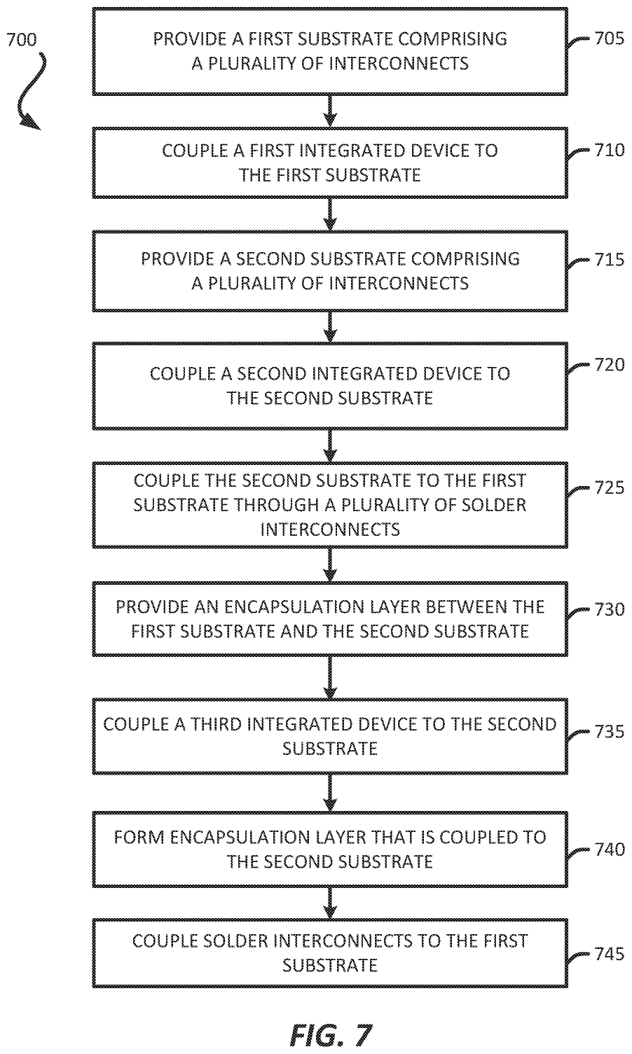

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 200 described in the disclosure. However, the method 700 may be used to provide or fabricate any of the packages (e.g., 300, 400) described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a first substrate that includes a plurality of interconnects. Stage 1 of FIG. 6A, illustrates and describes an example of a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described in FIGS. 8A-8B.

The method couples a first integrated device to the first substrate. Stage 2 of FIG. 6A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method provides (at 715) a second substrate comprising a plurality of interconnects. Stage 3 of FIG. 6A, illustrates and describes an example of a state after a substrate 104 is provided. The substrate 104 may be a second substrate. The substrate 104 includes at least one dielectric layer 140, a plurality of interconnects 142 and a solder resist layer 146. The substrate 104 may include a first surface (e.g., top surface) and a second surface (e.g., bottom surface). The substrate 104 may be fabricated using the method as described in FIGS. 8A-8B.

The method couples (at 720) a second integrated device to the second substrate. Stage 4 of FIG. 6A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method couples (at 725) a second substrate to a first substrate. Stage 5 of FIG. 6B, illustrates and describes an example of a state after the substrate 104 is coupled to the substrate 102 through the plurality of solder interconnects 106. A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of interconnects 122 and the plurality of interconnects 142. The substrate 104 is coupled to the substrate 102 such that the integrated device 103 and the integrated device 105 are located between the substrate 102 and the substrate 104. In some implementations, a plurality of solder interconnects are provided and/or coupled to the substrate 102 and the substrate 104 separately before coupling the substrate 104 to the substrate 102. In some implementations, the integrated device 105 may be coupled to the integrated device 103 through and adhesive (as shown in FIG. 3) or through a plurality of solder interconnects (as shown in FIG. 4). An underfill may be provided between the integrated device 105 may be coupled to the integrated device 103.

The method forms and couples (at 730) an encapsulation between the first substrate and the second substrate. Stage 6 of FIG. 6B, illustrates and describes an example of a state after an encapsulation layer 108 is provided between the substrate 102 and the substrate 104. The encapsulation layer 108 may at least partially encapsulate the integrated device 103, the integrated device 105, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method couples (at 735) integrated device(s) to the second substrate. Stage 7 of FIG. 6C, illustrates and describes an example of a state after an integrated device 207 is coupled to the first surface (e.g., top surface) of the substrate 104. The integrated device 207 may be a third integrated device. The integrated device 207 may be coupled to the substrate 104 through the plurality of solder interconnects 270. A solder reflow process may be used to couple the integrated device 207 to the substrate 104. Stage 7 of FIG. 6C also illustrates and describes an example of a state after the package 209 is coupled to the first surface (e.g., top surface) of the substrate 104. The package 209 may be coupled to the substrate 104 through the plurality of solder interconnects 290. A solder reflow process may be used to couple the package 209 to the substrate 104.

The method forms and couples (at 740) a second encapsulation layer to the second substrate. Stage 8 of FIG. 6C, illustrates and describes an example of a state after an encapsulation layer 208 is provided and coupled to the substrate 104. The encapsulation layer 208 may at least partially encapsulate the integrated device 207 and the package 209. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

The method couples (at 745) a plurality of solder interconnects to the first substrate. Stage 9 of FIG. 6D, illustrates and describes an example of a state after a plurality of solder interconnects 110 are coupled to the second surface of the substrate 102. A solder reflow process may be used to couple the plurality of solder interconnects 110 to the substrate 102. Stage 9 may illustrate the package 200. The package 200 may be fabricated one at a time or may be fabricated together as part of one or more wafers and then singulated into individual packages.

### Exemplary Sequence for Fabricating a Substrate

In some implementations, fabricating a substrate includes several processes. FIGS. 8A-8C illustrate an exemplary sequence for providing or fabricating a substrate. In some implementations, the sequence of FIGS. 8A-8C may be used to provide or fabricate the substrate 102. However, the process of FIGS. 8A-8C may be used to fabricate any of the substrates (e.g., 104) described in the disclosure.

It should be noted that the sequence of FIGS. 8A-8C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 8A, illustrates a state after a carrier 800 is provided. A seed layer 801 may be located over the carrier 800.

Stage 2 illustrates a state after a plurality of interconnects 812 are formed. The interconnects 812 may be located over the seed layer 801. A plating process and etching process may be used to form the plurality of interconnects 812. The interconnects 812 may represent at least some of the interconnects from the plurality of interconnects 122.

Stage 3 illustrates a state after a dielectric layer 810 is formed over the carrier 800, the seed layer 801 and the plurality of interconnects 812. A deposition and/or lamination process may be used to form the dielectric layer 810. The dielectric layer 810 may include prepreg and/or polyimide. The dielectric layer 810 may include a photo-imageable dielectric. However, different implementations may use different materials for the dielectric layer.

Stage 4 illustrates a state after a plurality of cavities 813 is formed in the dielectric layer 810. The plurality of cavities 813 may be formed using an etching process (e.g., photo etching process) or laser process.

Stage 5 illustrates a state after interconnects 822 are formed in and over the dielectric layer 810, including in and over the plurality of cavities 813. For example, a via, pad and/or traces may be formed. A plating process may be used to form the interconnects.

Stage 6, as shown in FIG. 8B, illustrates a state after a dielectric layer 820 is formed over the dielectric layer 810 and the plurality of interconnects 822. A deposition and/or lamination process may be used to form the dielectric layer 820. The dielectric layer 820 may include prepreg and/or polyimide. The dielectric layer 820 may include a photo-imageable dielectric. However, different implementations may use different materials for the dielectric layer.

Stage 7, illustrates a state after a plurality of cavities 823 is formed in the dielectric layer 120. The dielectric layer 120 may represent the dielectric layer 810 and/or the dielectric layer 820. The plurality of cavities 823 may be formed using an etching process (e.g., photo etching process) or laser process.

Stage 8 illustrates a state after interconnects 832 are formed in and over the dielectric layer 120, including in and over the plurality of cavities 823. For example, a via, pad and/or traces may be formed. A plating process may be used to form the interconnects.

Stage 9 illustrates a state after the carrier 800 is decoupled (e.g., detached, removed, grinded out) from at least one dielectric layer 120 and the seed layer 801, portions of the seed layer 801 are removed (e.g., etched out), leaving the substrate 102 that includes at least one dielectric layer 120 and the plurality of interconnects 122. The plurality of interconnects 122 may represent the plurality of interconnects 812, the plurality of interconnects 822 and/or the plurality of interconnects 832.

Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. The solder resist layer 124 and/or the solder resist layer 126 may include openings. An etching process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

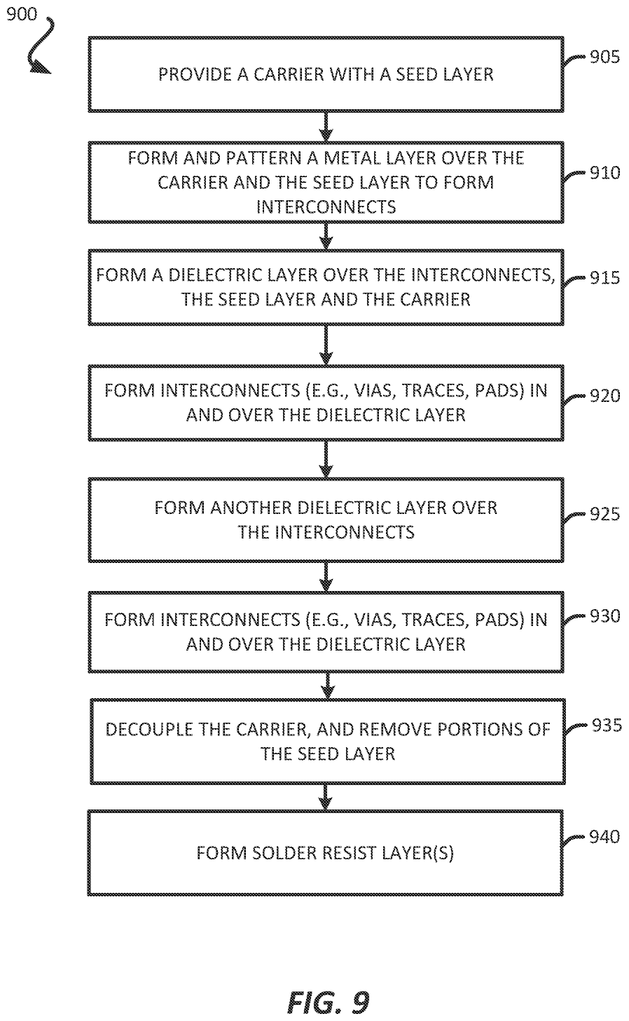

In some implementations, fabricating a substrate includes several processes. FIG. 9 illustrates an exemplary flow diagram of a method 900 for providing or fabricating a substrate. In some implementations, the method 900 of FIG. 9 may be used to provide or fabricate the substrate(s) of the disclosure. For example, the method 900 of FIG. 9 may be used to fabricate the substrate 102.

It should be noted that the method 900 of FIG. 9 may combine one or more processes in order to simplify and/or clarify the method for providing or fabricating a substrate. In some implementations, the order of the processes may be changed or modified.

The method provides (at 905) a carrier with a seed layer. Stage 1 of FIG. 8A, illustrates and describes an example of a state after a carrier 800 is provided. A seed layer 801 may be located over the carrier 800.

The method forms and patterns (at 910) a plurality of interconnects. Stage 2 of FIG. 8A, illustrates and describes an example of a state after a plurality of interconnects 812 are formed. The interconnects 812 may be located over the seed layer 801. A plating process and etching process may be used to form the plurality of interconnects 812. The interconnects 812 may represent at least some of the interconnects from the plurality of interconnects 122.

The method forms (at 915) a dielectric layer. Stage 3 of FIG. 8A, illustrates and describes an example of a state after a dielectric layer 810 is formed over the carrier 800, the seed layer 801 and the plurality of interconnects 812. A deposition and/or lamination process may be used to form the dielectric layer 810. The dielectric layer 810 may include prepreg and/or polyimide. The dielectric layer 810 may include a photo-imageable dielectric. However, different implementations may use different materials for the dielectric layer.

The method forms (at 920) a plurality of interconnects. Forming a plurality of interconnects may including forming a plurality of cavities in a dielectric layer and a performing a plating process. Stage 4 of FIG. 8A, illustrates and describes an example of a state after a plurality of cavities 813 is formed in the dielectric layer 810. The plurality of cavities 813 may be formed using an etching process (e.g., photo etching process) or laser process.

Stage 5 of FIG. 8A, illustrates and describes an example of a state after interconnects 822 are formed in and over the dielectric layer 810, including in and over the plurality of cavities 813. For example, a via, pad and/or traces may be formed. A plating process may be used to form the interconnects.

The method forms (at 925) another dielectric layer. Stage 6 of FIG. 8B, illustrates and describes an example of a state after a dielectric layer 820 is formed over the dielectric layer 810 and the plurality of interconnects 822. A deposition and/or lamination process may be used to form the dielectric layer 820. The dielectric layer 820 may include prepreg and/or polyimide. The dielectric layer 820 may include a photo-imageable dielectric. However, different implementations may use different materials for the dielectric layer.

The method forms (at 930) a plurality of interconnects. Forming a plurality of interconnects may including forming a plurality of cavities in a dielectric layer and a performing a plating process. Stage 7 of FIG. 8B, illustrates and describes an example of a state after a plurality of cavities 823 is formed in the dielectric layer 120. The dielectric layer 120 may represent the dielectric layer 810 and/or the dielectric layer 820. The plurality of cavities 823 may be formed using an etching process (e.g., photo etching process) or laser process.

Stage 8 of FIG. 8B, illustrates and describes an example of a state after interconnects 832 are formed in and over the dielectric layer 120, including in and over the plurality of cavities 823. For example, a via, pad and/or traces may be formed. A plating process may be used to form the interconnects.

The method decouples (at 935) a carrier. Stage 8 of FIG. 8B, illustrates and describes an example of a state after the carrier 800 is decoupled (e.g., detached, removed, grinded out) from at least one dielectric layer 120 and the seed layer 801, portions of the seed layer 801 are removed (e.g., etched out), leaving the substrate 102 that includes at least one dielectric layer 120 and the plurality of interconnects 122. The plurality of interconnects 122 may represent the plurality of interconnects 812, the plurality of interconnects 822 and/or the plurality of interconnects 832.

The method forms (at 940) solder resist layers. Stage 10 of FIG. 8B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. An etching process may be used to form the openings and/or the openings in the solder resist layer 124 and/or the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

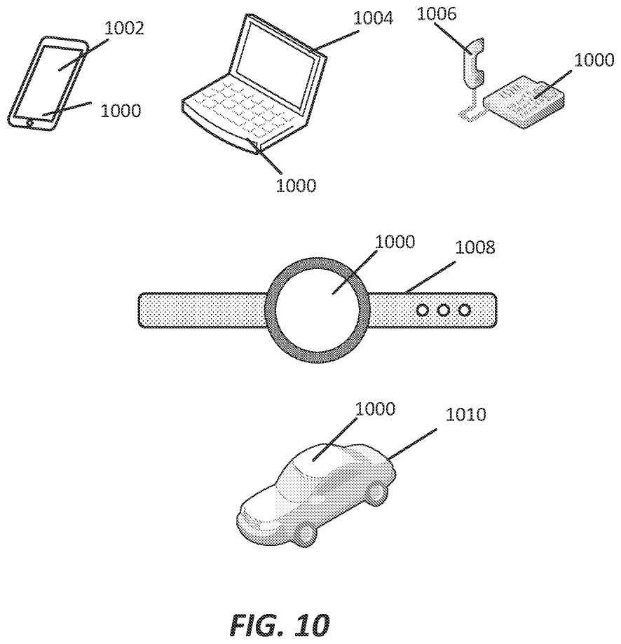

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6D, 7, 8A-8B, and 9-10 may be rearranged and/or combined into a single component, process, feature or function or embodied in several components, processes, or functions. Additional elements, components, processes, and/or functions may also be added without departing from the disclosure. It should also be noted FIGS. 1-5, 6A-6D, 7, 8A-8B, and 9-10 and its corresponding description in the present disclosure is not limited to dies and/or ICs. In some implementations, FIGS. 1-5, 6A-6D, 7, 8A-8B, and 9-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a first substrate; a first integrated device coupled to the first substrate; a second substrate; a second integrated device coupled to the second substrate; and an encapsulation layer coupled to the first substrate and the second substrate, wherein the encapsulation layer, the first integrated device and the second integrated device are located between the first substrate and the second substrate.
Aspect 2: The package of aspect 1, further comprising an adhesive coupled to the first integrated device and the second integrated device, wherein the adhesive is located between the first integrated device and the second integrated device.
Aspect 3: The package of aspect 1, wherein the first integrated device is coupled to the second integrated device through a plurality of solder interconnects.
Aspect 4: The package of aspect 3, wherein the first integrated device comprises a first plurality of through substrate vias.
Aspect 5: The package of aspect 4, wherein the second integrated device comprises a second plurality of through substrate vias.
Aspect 6: The package of aspects 3 through 5, wherein an electrical path between the first integrated device and the second integrated device comprises the plurality of solder interconnects between the first integrated device and the second integrated device.
Aspect 7: The package of aspects 1 through 6, further comprising a plurality of solder interconnects, wherein the first substrate is configured to be electrically coupled to the second substrate through the plurality of solder interconnects.
Aspect 8: The package of aspects 1 through 7, wherein the first substrate comprises a first surface and a second surface, wherein the second substrate comprises a first surface and a second surface, wherein the first integrated device is coupled to the second surface of the first substrate, and wherein the second integrated device is coupled to the first surface of the first substrate.
Aspect 9: The package of aspect 8, further comprising a third integrated device coupled to the second surface of the second substrate.
Aspect 10: The package of aspect 9, further comprising a second encapsulation layer coupled to the second surface of the second substrate, wherein the second encapsulation layer at least partially encapsulates the third integrated device.
Aspect 11: A method for fabricating a package. The method provides a first substrate. The method couples a first integrated device to the first substrate. The method provides a second substrate. The method couples a second integrated device to the second substrate. The method forms an encapsulation layer that is coupled to the first substrate and the second substrate, wherein the encapsulation layer, the first integrated device and the second integrated device are located between the first substrate and the second substrate.
Aspect 12: The method of aspect 11, further comprising providing an adhesive that is coupled to the first integrated device and the second integrated device, wherein the adhesive is located between the first integrated device and the second integrated device.
Aspect 13: The method of aspect 11, wherein the first integrated device is coupled to the second integrated device through a plurality of solder interconnects.
Aspect 14: The method of aspect 13, wherein the first integrated device comprises a first plurality of through substrate vias.
Aspect 15: The method of aspect 14, wherein the second integrated device comprises a second plurality of through substrate vias.
Aspect 16: The method of aspects 13 through 15, wherein an electrical path between the first integrated device and the second integrated device comprises the plurality of solder interconnects between the first integrated device and the second integrated device.
Aspect 17: The method of aspects 11 through 16, further coupling a plurality of solder interconnects to the first substrate and the second substrate, wherein the first substrate is configured to be electrically coupled to the second substrate through the plurality of solder interconnects.
Aspect 18: The method of aspects 11 through 17, wherein the first substrate comprises a first surface and a second surface, wherein the second substrate comprises a first surface and a second surface, wherein the first integrated device is coupled to the second surface of the first substrate, and wherein the second integrated device is coupled to the first surface of the first substrate.
Aspect 19: The method of aspect 18, further comprising coupling a third integrated device to the second surface of the second substrate.
Aspect 20: The method of aspect 19, further comprising forming a second encapsulation layer that is coupled to the second surface of the second substrate, wherein the second encapsulation layer at least partially encapsulates the third integrated device.
Aspect 21: The package of aspects 1 through 10, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
a first integrated device coupled to the first substrate;
a second substrate;
a second integrated device coupled to the second substrate; and
an encapsulation layer coupled to the first substrate and the second substrate, wherein the encapsulation layer, the first integrated device and the second integrated device are located between the first substrate and the second substrate.

2. The package of claim 1, further comprising an adhesive coupled to the first integrated device and the second integrated device, wherein the adhesive is located between the first integrated device and the second integrated device.

3. The package of claim 1, wherein the first integrated device is coupled to the second integrated device through a plurality of solder interconnects.

4. The package of claim 3, wherein the first integrated device comprises a first plurality of through substrate vias.

5. The package of claim 4, wherein the second integrated device comprises a second plurality of through substrate vias.

6. The package of claim 3, wherein an electrical path between the first integrated device and the second integrated device comprises the plurality of solder interconnects between the first integrated device and the second integrated device.

7. The package of claim 1, further comprising a plurality of solder interconnects, wherein the first substrate is configured to be electrically coupled to the second substrate through the plurality of solder interconnects.

8. The package of claim 1,
wherein the first substrate comprises a first surface and a second surface,
wherein the second substrate comprises a first surface and a second surface,
wherein the first integrated device is coupled to the second surface of the first substrate, and
wherein the second integrated device is coupled to the first surface of the first substrate.

9. The package of claim 8, further comprising a third integrated device coupled to the second surface of the second substrate.

10. The package of claim 9, further comprising a second encapsulation layer coupled to the second surface of the second substrate, wherein the second encapsulation layer at least partially encapsulates the third integrated device.

11. A method for fabricating a package, comprising:
providing a first substrate;
coupling a first integrated device to the first substrate;
providing a second substrate;
coupling a second integrated device to the second substrate; and
forming an encapsulation layer that is coupled to the first substrate and the second substrate, wherein the encapsulation layer, the first integrated device and the second integrated device are located between the first substrate and the second substrate.

12. The method of claim 11, further comprising providing an adhesive that is coupled to the first integrated device and the second integrated device, wherein the adhesive is located between the first integrated device and the second integrated device.

13. The method of claim 11, wherein the first integrated device is coupled to the second integrated device through a plurality of solder interconnects.

14. The method of claim 13, wherein the first integrated device comprises a first plurality of through substrate vias.

15. The method of claim 14, wherein the second integrated device comprises a second plurality of through substrate vias.

16. The method of claim 13, wherein an electrical path between the first integrated device and the second integrated device comprises the plurality of solder interconnects between the first integrated device and the second integrated device.

17. The method of claim 11, further coupling a plurality of solder interconnects to the first substrate and the second substrate, wherein the first substrate is configured to be electrically coupled to the second substrate through the plurality of solder interconnects.

18. The method of claim 11,
wherein the first substrate comprises a first surface and a second surface,
wherein the second substrate comprises a first surface and a second surface,
wherein the first integrated device is coupled to the second surface of the first substrate, and
wherein the second integrated device is coupled to the first surface of the first substrate.

19. The method of claim 18, further comprising coupling a third integrated device to the second surface of the second substrate.

20. The method of claim 19, further comprising forming a second encapsulation layer that is coupled to the second surface of the second substrate, wherein the second encapsulation layer at least partially encapsulates the third integrated device.
